(19) United States
(12) Patent Application Publication
(10) Pub. No.: US 2010/0085130 A1
(43) Pub. Date: Apr. 8, 2010

(54) MANUFACTURABLE TUNABLE MATCHING NETWORK FOR WIRE AND RIBBON BOND COMPENSATION

(75) Inventor: Alexandros Margomenos, Ann Arbor, MI (US)

Correspondence Address: GIFFORD, KRASS, SPRINKLE,;ANDERSON & CITKOWSKI, P.C., P.O. BOX 7021, TROY, MI, 48007-7021, US

(73) Assignee: Toyota Motor Engineering & Manufacturing North America, Inc., Erlanger, KY (US)

(21) Appl. No.: 12/244,807

(22) Filed: Oct. 3, 2008

(51) Int. Cl. H03H 7/38

(52) U.S. Cl. 333/33

(57) ABSTRACT

In a millimeter wave circuit having first and second adjacent circuit boards, each circuit board having a microstrip and a ground plane, a low loss electrical connection between the microstrips on adjacent planes. Each microstrip ends in a connection pad and a first wire bond is attached to the connection pads on the adjacent circuit boards. A second wire bond also extends between the connection pads in parallel with the first wire bond and, optionally, one or more capacitors are provided on either the first, second or both circuit boards to match the impedance between the circuit boards. These capacitors may be selectively trimmed.

### BACKGROUND OF THE INVENTION

I. Field of the Invention

The present invention relates generally to millimeter wave circuits and, more particularly, to a low loss electrical connection between adjacent high frequency circuit boards.

II. Description of Material Art

Electrical connections between adjacent circuit boards in millimeter wave applications present many challenges. Such circuits are used, for example, in automotive radar applications in the 77 gigahertz range. Such applications, furthermore, are typically low powered so that a low loss electrical connection between adjacent circuit boards is important in order to achieve proper operation of the overall circuit.

In such millimeter wave applications, these circuit boards include a ground plane on one side of a substrate and a microstrip on the opposite side of the substrate and thus spaced from the ground plane. The microstrip terminates in a connection pad along one edge of the circuit board. Similarly, an adjacent circuit board also includes a microstrip and ground plane as well as a connection pad along one edge of the second circuit board. The connection pads are aligned with each other and a wire bond or ribbon bond—hereinafter collectively referred to as wire bonds—electrically connects the two connection pads together and thus electrically connects the two microstrips together for transmission of the high frequency (radio frequency-RF) signal.

Due to the high frequency of the RF signal, the wire bonds between adjacent connection pads on the adjacent circuit boards present a small, but significant, inductance. Furthermore, any misalignment between the connection pads and the adjacent circuit boards, or a misalignment of the wire bond or difference in the length of the wire bond will vary the inductance of the wire bond and thus adversely affect the impedance match between the two circuit boards. Such an impedance mismatch creates signal loss in the transmission of the microwave radio frequency signal from one microstrip to the second microstrip on the two circuit boards which, in turn, adversely affects the overall operation of the microwave system.

### SUMMARY OF THE PRESENT INVENTION

The present invention provides an approach to connecting microstrips on adjacent circuit boards in millimeter wave radio frequency applications.

In one approach, the size of the connection pads which terminate the microstrips on the adjacent circuit boards is enlarged. Thereafter, a first wire bond connects the connection pads together while a second wire bond extends between the connection pads in parallel with the first wire bond. The provision of two wire bonds in parallel with each other effectively reduces the inductance of the connection between the two connection pads by approximately one half. In some applications, such reduction in the inductance may be sufficient to create an acceptable impedance match between the microstrips on the adjacent circuit boards for the overall operation of the microwave system.

If the provision for the two wire bonds between the adjacent connection pads does not result in an acceptable impedance match between the two connection pads, and thus between the two microstrips on the adjacent circuit boards, one or more capacitors may be added to one or both of the circuit boards. These capacitors may be trimmed in order to obtain a resonant or near resonant circuit at the desired frequency of operation for the system. These capacitors, for example, may comprise MAM or MIM capacitors and may be selectively added to one or both of the circuit boards as required.

Alternatively, one or both of the microstrips may include a stub line extending laterally from the microstrip. One or more capacitors then electrically connect the stub line to the ground plane and these capacitors may be selectively removed from the circuit by interrupting the stub line. Similarly, a trimmable capacitive stub may also be electrically connected to one or both of the microstrips on the circuit boards.

### BRIEF DESCRIPTION OF THE DRAWING

A better understanding of the present invention will be had upon reference to the following detailed description when read in conjunction with the accompanying drawing, wherein like reference characters refer to like parts throughout the several views, and in which:

FIG. 1 is a top fragmentary plan view illustrating two adjacent circuit boards in a millimeter wave system and which have not yet been electrically connected together;

FIG. 2 is a view taken substantially along line 2-2 in FIG. 1; [Please add line 2-2 in FIG. 1]

FIG. 3 is an elevational view illustrating a preferred embodiment of the present invention;

FIG. 4 is a view similar to FIG. 3, but illustrating a modification thereof;

FIG. 5 is a view similar to FIG. 3, but illustrating a modification thereof;

FIG. 6 is a view similar to FIG. 3, but illustrating a modification thereof; and

FIG. 7 is a view similar to FIG. 3, but illustrating a modification thereof.

### DETAILED DESCRIPTION OF A PREFERRED EMBODIMENT OF THE PRESENT INVENTION

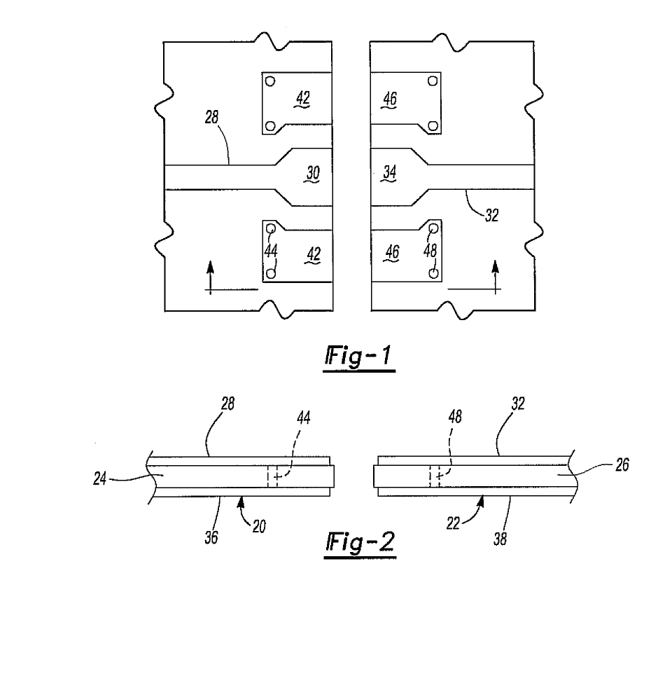

With reference first to FIGS. 1 and 2, a first circuit board 20 and a second circuit board 22 are illustrated for use in a millimeter wave system. As used herein, such systems convey radio frequency in the millimeter range, e.g. 77 gigahertz. Such a high frequency RF signal is used, for example, in automotive radar applications.

Each circuit board 20 and 22 includes its own substrate 24 and 26, respectively, constructed of an electrically insulating material. A first microstrip 28 extends along a top of the first circuit board 20 and terminates in a connection pad 30. Similarly, a second microstrip 32 extends along the top of the insulating substrate 26 of the second circuit board 22 and also terminates in a connection pad 34. In order to electrically connect the microstrips 28 and 32 together, the connection pads 30 and 34 are aligned and adjacent each other.

Still referring to FIGS. 1 and 2, the circuit boards 20 and 22 also include a ground plane 36 and 38, respectively, on the bottom surface of the substrates 24 and 26. The ground plane 36 is electrically connected to two ground pads 42 on opposite sides of the connection pad 30 by vias 44 so that the ground pads 42 are electrically connected to the ground plane 36. Similarly, ground pads 46 are positioned on opposite sides of the connection pad 34 on the second circuit board 22. The ground pads 46 are also connected to the ground plane 38 of the second circuit board 22 by vias 48. Preferably, the connection pads 30 and 34 as well as the ground pads 42 and 46 all extend to the edge of their respective circuit boards 20 or 22.

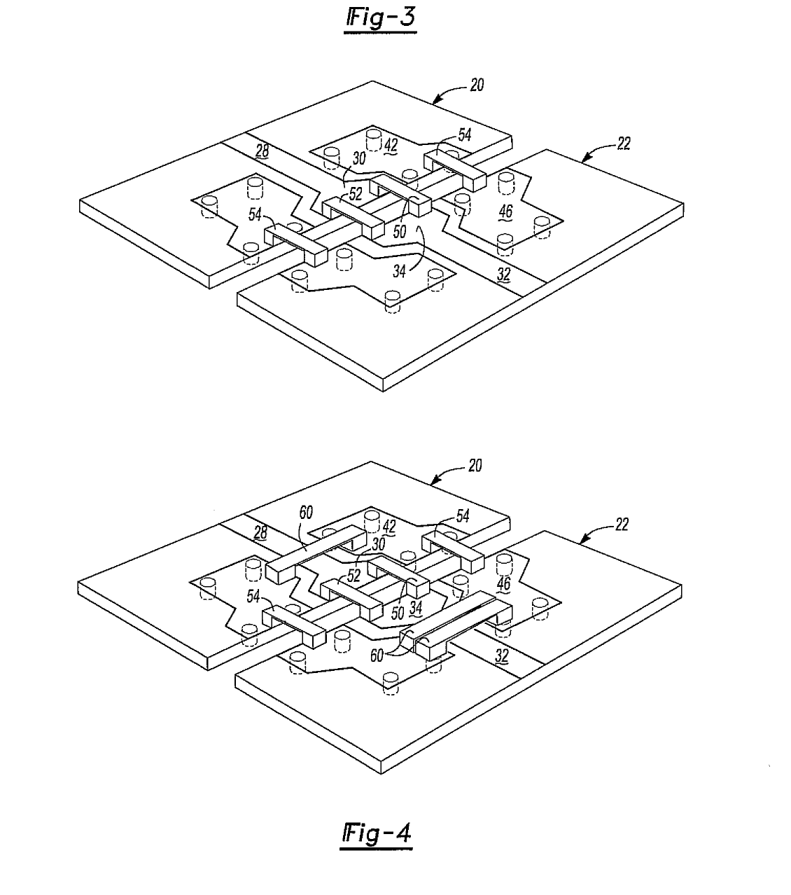

With reference now to FIG. 3, in order to electrically connect the microstrips 28 and 32 together on the first and second circuit boards 20 and 22, respectively, two wire bonds 50 and 52, which collectively includes both wire bonds as well as ribbon bonds, are electrically connected in parallel with each other between the connection pads 30 and 34 on the first and second circuit boards 20 and 22, respectively. The provision of the two wire bonds 50 and 52 in parallel reduces the inductance by approximately one half as compared with a single wire bond between the connection pads 30 and 34, which for some applications may result in an adequate impedance match between the microstrips 28 and 32.

Still referring to FIG. 3, wire bonds 54 are also provided between the ground pads 42 and 46 on the circuit boards 20 and 22, respectively. These wire bonds 54 thus electrically connect the ground planes 36 and 38 of the first and second circuit boards 20 and 22 together.

With reference now to FIG. 4, in some cases the use of the two wire bonds 50 and 52 for connecting the microstrips 28 and 32 together will not be sufficient for an acceptable impedance match between the microstrips 28 and 32. In such cases, it is desirable to selectively add capacitance to the connection between the microstrips 28 and 32 so that a resonance or near resonance between the inductance of the wire bonds 50 and 52 and the capacitance is achieved at the desired frequency. Resonance, of course, results in the maximum transmission of the RF signal between the microstrips 28 and 32.

In order to add capacitance to the connection between the microstrips 28 and 34, one or more wire bonds 60 extend between the ground pads 42 or 46 on either or both of the circuit boards 20 and 22. Consequently, the wire bonds 60 overlie a portion of the microstrip 28 or 32 of their associated circuit board 20 or 22. Since the wire bond itself is made of metal, a small capacitance is created between the wire bonds 60 and the microstrip 28 or 32.

Still referring to FIG. 4, additional wire bonds, each creating additional capacitance, may be added as required during the manufacture of the overall microwave system which includes the circuit boards 20 and 22. For example, a single wire bond 60 is shown interconnecting the ground pads 42 of the first circuit board 20 and, by way of example, two wire bonds 60 are shown interconnecting the ground pad 46 of the second circuit board 22. Preferably, during the manufacture of the overall microwave system which includes the circuit boards 20 and 22, the circuit boards 20 and 22 will be subjected to testing and sufficient capacitance added to the circuit board 20 and/or 22 as desired in order to obtain an acceptable impedance match between the two microstrips 28 and 32.

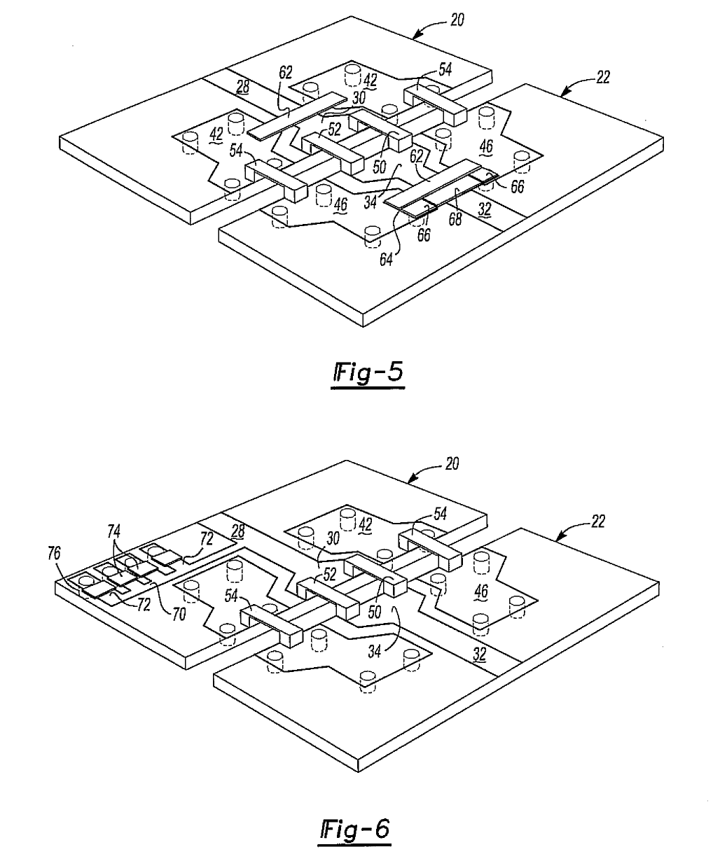

With reference now to FIG. 5, FIG. 5 differs from FIG. 4 in that discrete capacitors 62, rather than simple wire bonds, interconnect the ground pads 42 on the first circuit board 20 and/or the ground pads 46 on second circuit board 22 to add capacitance to the circuit to obtain a desired resonant or near resonant frequency. These capacitors 62, like the wire bond 60 in FIG. 4, overlie the microstrip 28 or 32 on their associated circuit board 20 or 22 respectively. These capacitors 62 may comprise, for example, MIM capacitors or MAM capacitors.

Still referring to FIG. 5, a trimmable capacitor 64 may also be provided across the ground pads on one or both of the circuit boards 20 and 22. The trimmable capacitor 64 includes one or more slots 66 which extend through the metal layer of the capacitor 64. As such, a center portion 68 of the capacitor 64 which overlies the microstrip 32 is not connected to ground but, rather, floats and presents a relatively low capacitance. To increase or trim the capacitance of the capacitor 64, the slot 66 may be filled with a conductive material, such as a conductive epoxy, as required to tune the circuit to achieve resonant frequency.

With reference now to FIG. 6, a still further approach to selectively add capacitance to one or both of the circuit boards 20 and 22 is illustrated. A stub line 70 extends laterally outwardly from the microstrip 28. A plurality of lines 72 extend outwardly from the stub line 70 at different spacings from the microstrip 28. A capacitor 74 in turn is electrically connected between each line section 72 and the ground plane through vias 76. These capacitors 74, furthermore, may be of any conventional construction such as MAM or MIM capacitors. Still referring to FIG. 6, the amount of capacitance added to the circuit board connection may be varied by selectively electrically disconnecting the capacitor 74 from the circuit. This is accomplished by removing a portion of the line section 72 thus electrically disconnecting the capacitor 74 associated with the line section 72 from the circuit.

Furthermore, although the stub line 70 and its associated components are illustrated in FIG. 6 as associated with only the circuit board 20, it will be appreciated that a like stub line with the associated components may also be associated with the second circuit board 22.

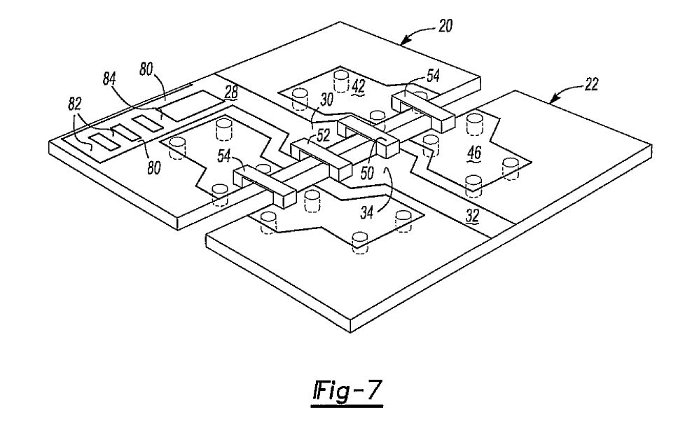

Referring now to FIG. 7, a still farther approach to selectively adding capacitance to the electrical connection between the two circuit boards is illustrated. A pair of parallel stub lines 80 and 82 are electrically connected to and extend laterally outwardly from the microstrip 28. A plurality of spaced line sections 82 then electrically connect the stub lines 80 together. The line segments 82 are positioned at different distances from the microstrip 28.

The spacing between the line sections 82 and the microstrip 28 determines the amount of capacitance added to the overall circuit by the line sections 82. These line sections 82 may be selectively removed by simply removing a portion of the desired line section 82, as shown at 84, thus electrically disconnecting the line section 82 from the circuit.

In practice, the various approaches to add or delete the capacitance in an attempt to obtain a resonant or near resonant circuit may be performed on an individual basis during the manufacture of the overall system containing the two circuit boards 20 and 22. For example, during the manufacture of the microwave system, the impedance match between the two circuit boards 20 and 22 may be tested and the capacitance added or deleted as required until an acceptable impedance match is obtained.

From the foregoing, it can be seen that the present invention provides a simple and yet highly effective mechanism for obtaining an acceptable impedance match between adjacent circuit boards in a microwave system. Having described my invention, however, many modifications thereto will become apparent to those skilled in the art to which it pertains without deviation from the spirit of the invention as defined by the scope of the appended claims.

I claim:

1. In a millimeter wave circuit having a first and second adjacent circuit boards, said first circuit board having at least one first microstrip and said second circuit board having at least one second microstrip for conducting microwave radiation, said first and second microstrips each terminating in a connection pad adjacent an edge of said first and second circuit board, respectively, so that said connection pads are closely adjacent each other, a low loss electrical connection between said microstrips on said circuit boards comprising:
a first wire bond extending between said connection pads, and
a second wire bond extending between said connection pads in parallel with said first wire bond.

2. The invention as defined in claim 1 wherein each circuit board includes a ground plane and comprising a capacitor electrically disposed between at least one of said first and second microstrips and the ground plane associated with said at least one of said first and second microstrips.

3. The invention as defined in claim 2 wherein said capacitor comprises a metal layer electrically connected to said ground plane and having a portion extending over one of said first and second microstrips.

4. The invention as defined in claim 3 wherein said portion of said metal layer is positioned adjacent said connection pad on said at least one of said first and second microstrips.

5. The invention as defined in claim 2 and including ground pads electrically connected to the ground plane on said circuit board for said at least one of said first and second microstrips, said ground pads being positioned on opposite sides of said at least one of said first and second microstrips, and said capacitor comprising a wire bond extending between and connected to said ground pads and over said at least one of said first and second microstrips.

6. The invention as defined in claim 5 and comprising a plurality of wire bonds extending between and connected to said ground pads and over said at least one of said first and second microstrips.

7. The invention as defined in claim 2 and including ground pads electrically connected to the ground plane, said ground pads being positioned on opposite sides of said at least one of said first and second microstrips, and said capacitor comprising a MIM capacitor extending between and connected to said ground pads so that said MIM capacitor overlies said at least one of said first and second microstrips.

8. The invention as defined in claim 7 wherein said MIM capacitor includes at least one slot extending though a metallic layer of said MIM to thereby separate said metallic layer from the ground plane, said slot being optionally fillable by a conductive material.

9. The invention as defined in claim 2 and including ground pads electrically connected to the ground plane, said ground pads being positioned on opposite sides of said at least one of said first and second microstrips, and said capacitor comprising a MAM capacitor extending between and connected to said ground pads so that said MAM capacitor overlies said at least one of said first and second microstrips.

10. The invention as defined in claim 1 and comprising a stub strip electrically connected to and extending laterally outwardly from at least one of said first and second microstrips, at least one capacitor electrically connected between said stub strip and said ground plane.

11. The invention as defined in claim 10 and comprising at least two capacitors electrically connected between said stub strip and said ground plane, said capacitors being at different spaced distances from at least one of said first and second microstrips.

12. The invention as defined in claim 11 wherein said stub strip includes at least one removable portion to selectively electrically disconnect at least one capacitor from at least one of said first and second microstrips.

13. The invention as defined in claim 1 and comprising a stub strip electrically connected to and extending laterally outwardly from at least one of said first and second microstrips, said stub strip having at least two selectively removable line sections, said line sections being at different spacings from said at least one of said first and second microstrips.

14. In a millimeter wave circuit having a first and second adjacent circuit boards, said first circuit board having at least one first microstrip and said second circuit board having at least one second microstrip for conducting microwave radiation, each circuit board having a ground plane, said first and second microstrips each terminating in a connection pad adjacent an edge of said first and second circuit board, respectively, so that said connection pads are closely adjacent each other, a low loss electrical connection between said microstrips on said circuit boards comprising:
at least one wire bond extending between said connection pads, and
a capacitor electrically disposed between at least one of said first and second microstrips and the ground plane associated with said at least one of said first and second microstrips.

15. The invention as defined in claim 14 wherein said capacitor comprises a metal layer electrically connected to said ground plane and having a portion extending over one of said first and second microstrips.

16. The invention as defined in claim 15 wherein said portion of said metal layer is positioned adjacent said connection pad on said at least one of said first and second microstrips.

17. The invention as defined in claim 14 and including ground pads electrically connected to the ground plane on said circuit board for said at least one of said first and second microstrips, said ground pads being positioned on opposite sides of said at least one of said first and second microstrips, and said capacitor comprising a wire bond extending between and connected to said ground pads and over said at least one of said first and second microstrips.

18. The invention as defined in claim 17 and comprising a plurality of wire bonds extending between and connected to said ground pads and over said at least one of said first and second microstrips.

19. The invention as defined in claim 14 and including ground pads electrically connected to the ground plane, said ground pads being positioned on opposite sides of said at least one of said first and second microstrips, and said capacitor comprising a MIM capacitor extending between and connected to said ground pads so that said MIM capacitor overlies said at least one of said first and second microstrips.

20. The invention as defined in claim 19 wherein said MIM capacitor includes at least one slot extending though a metallic layer of said MIM to thereby separate said metallic layer from the ground plane, said slot being optionally fillable by a conductive material.

21. The invention as defined in claim 14 and including ground pads electrically connected to the ground plane, said ground pads being positioned on opposite sides of said at least one of said first and second microstrips, and said capacitor comprising a MAM capacitor extending between and connected to said ground pads so that said MAM capacitor overlies said at least one of said first and second microstrips.

22. The invention as defined in claim 14 and comprising a stub strip electrically connected to and extending laterally outwardly from at least one of said first and second microstrips, at least one capacitor electrically connected between said stub strip and said ground plane.

23. The invention as defined in claim 22 and comprising at least two capacitors electrically connected between said stub strip and said ground plane, said capacitors being at different spaced distances from at least one of said first and second microstrips.

24. The invention as defined in claim 23 wherein said stub strip includes at least one removable portion to selectively electrically disconnect at least one capacitor from at least one of said first and second microstrips.

25. The invention as defined in claim 14 and comprising a stub strip electrically connected to and extending laterally outwardly from at least one of said first and second microstrips, said stub strip having at least two selectively removable line sections, said line sections being at different spacings from said at least one of said first and second microstrips.
